(19) United States
(12) Patent Application Publication
(10) Pub. No.: US 2024/0324470 A1
(43) Pub. Date: Sep. 26, 2024

(54) MAGNETIC MEMORY DEVICE

(71) Applicant: Kioxia Corporation, Tokyo (JP)

(72) Inventors: Naoki AKIYAMA, Seoul (KR); Kenichi YOSHINO, Seongnam-si Gyeonggi-do (KR); Kazuya SAWADA, Seoul (KR); Takuya SHIMANO, Seoul (KR); Hyungjun CHO, Seoul (KR)

(73) Assignee: Kioxia Corporation, Tokyo (JP)

(21) Appl. No.: 18/606,182

(22) Filed: Mar. 15, 2024

(30) Foreign Application Priority Data
Mar. 22, 2023 (JP) 2023-045242

(51) Int. Cl. H10N 50/80; H10B 61/00; H10N 50/01; H10N 50/10

(52) U.S. Cl. CPC H10N 50/80; H10B 61/10; H10N 50/01; H10N 50/10

(57) ABSTRACT

According to one embodiment, a magnetic memory device includes a lower structure, a bottom electrode provided on the lower structure and formed of a conductive material, a top electrode provided above the bottom electrode, a magnetoresistance effect element provided between the bottom electrode and the top electrode, and an oxide insulating layer including a first portion provided on a side surface of the bottom electrode and a second portion provided on a side surface of the magnetoresistance effect element, and formed of an oxide of the conductive material.

### CROSS-REFERENCE TO RELATED APPLICATIONS

This application is based upon and claims the benefit of priority from Japanese Patent Application No. 2023-045242, filed Mar. 22, 2023, the entire contents of which are incorporated herein by reference.

### FIELD

Embodiments described herein relate generally to a magnetic memory device.

### BACKGROUND

A magnetic memory device has been proposed in which memory cells including magnetoresistance effect elements are integrated on a semiconductor substrate.

### BRIEF DESCRIPTION OF THE DRAWINGS

FIG. 1 is a perspective view schematically showing a basic configuration of a magnetic memory device according to a first embodiment.

FIG. 2 is a cross-sectional view schematically showing a configuration of an area where memory cells of the magnetic memory device according to the first embodiment are provided.

FIG. 3 is a cross-sectional view schematically illustrating a part of a method of manufacturing the magnetic memory device according to the first embodiment.

FIG. 4 is a cross-sectional view schematically illustrating a part of the method of manufacturing the magnetic memory device according to the first embodiment.

FIG. 5 is a cross-sectional view schematically illustrating a part of the method of manufacturing the magnetic memory device according to the first embodiment.

FIG. 6 is a cross-sectional view schematically illustrating a part of the method of manufacturing the magnetic memory device according to the first embodiment.

FIG. 7 is a cross-sectional view schematically showing a configuration of an area where memory cells of a magnetic memory device according to the second embodiment are provided.

FIG. 8 is a cross-sectional view schematically illustrating a part of a method of manufacturing the magnetic memory device according to the second embodiment.

FIG. 9 is a cross-sectional view schematically illustrating a part of the method of manufacturing the magnetic memory device according to the second embodiment.

FIG. 10 is a cross-sectional view schematically illustrating a part of the method of manufacturing the magnetic memory device according to the second embodiment.

FIG. 11 is a cross-sectional view schematically illustrating a part of the method of manufacturing the magnetic memory device according to the second embodiment.

### DETAILED DESCRIPTION

In general, according to one embodiment, a magnetic memory device includes: a lower structure; a bottom electrode provided on the lower structure and formed of a conductive material; a top electrode provided above the bottom electrode; a magnetoresistance effect element provided between the bottom electrode and the top electrode; and an oxide insulating layer including a first portion provided on a side surface of the bottom electrode and a second portion provided on a side surface of the magnetoresistance effect element, and formed of an oxide of the conductive material.

Embodiments will be described hereinafter with reference to the accompanying drawings.

### First Embodiment

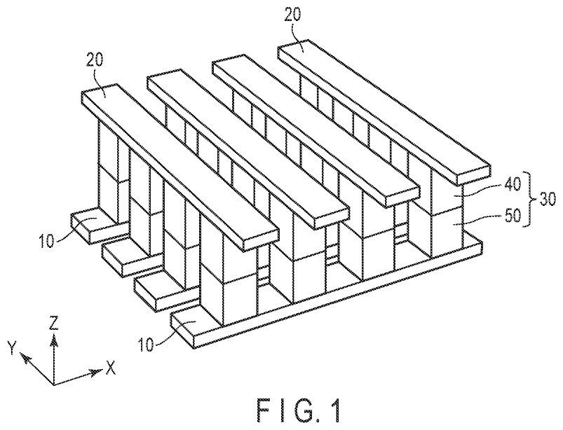

FIG. 1 is a perspective view schematically showing a basic configuration of a magnetic memory device according to the first embodiment.

As shown in FIG. 1, the magnetic memory device includes a plurality of first wiring lines 10 extending along an X direction, a plurality of second wiring lines 20 extending along a Y direction, and a plurality of memory cells 30 each provided between a respective one of the first wiring lines 10 and a respective one of the second wiring lines 20. The first wiring lines 10 correspond to word lines and the second wiring lines 20 correspond to bit lines, or vice versa. The X direction, Y direction, and Z direction intersect each other. More specifically, the X, Y, and Z directions are orthogonal to each other.

The memory cells 30 each have a configuration in which a magnetoresistance effect element 40 and a selector (switching element) 50 are connected in series, and the magnetoresistance effect element 40 is stacked on the selector 50.

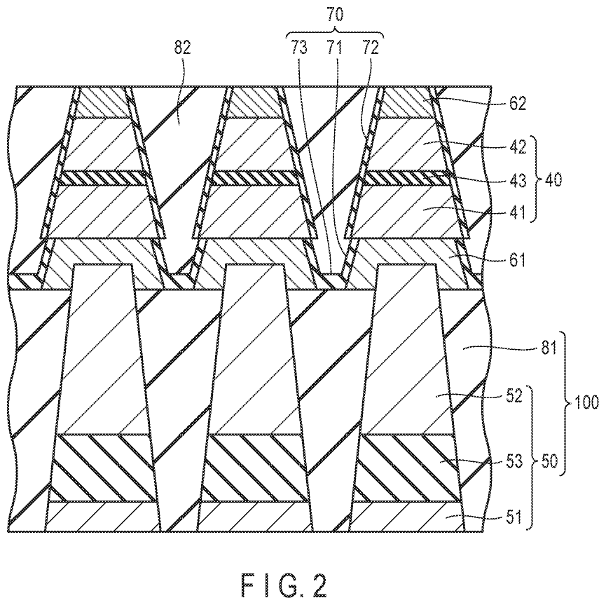

FIG. 2 is a cross-sectional view schematically showing a configuration of an area where the memory cells 30 are provided.

The configuration shown in FIG. 2 is provided above a semiconductor substrate (not shown) and includes a lower structure 100 including the selector 50 and an interlayer insulating layer 81, a bottom electrode 61 provided on the lower structure 100, a top electrode 62 provided above the bottom electrode 61, the magnetoresistance effect element 40 provided between the bottom electrode 61 and the top electrode 62, an oxide insulating layer 70, and an interlayer insulating layer 82.

The magnetoresistance effect element 40 is a magnetic tunnel junction (MTJ) element and includes a storage layer (first magnetic layer) 41, a reference layer (second magnetic layer) 42, and a tunnel barrier layer (nonmagnetic layer) 43.

The storage layer 41 is a ferromagnetic layer having a variable magnetization direction and is formed, for example, of a CoFeB layer containing cobalt (Co), iron (Fe), and boron (B). The variable magnetization direction means that the magnetization direction changes for a given write current.

The reference layer 42 is a ferromagnetic layer having a fixed magnetization direction and includes two layers with antiferromagnetic coupling. More specifically, the reference layer 42 has a stacked structure in which, for example, a CoFeB layer containing cobalt (Co), iron (Fe), and boron (B) and a superlattice layer of cobalt (Co) and platinum (Pt) are stacked one on another. The fixed magnetization direction means that the magnetization direction does not change for a given write current.

The tunnel barrier layer 43 is an insulating layer provided between the storage layer 41 and the reference layer 42, and is formed, for example, of an MgO layer containing magnesium (Mg) and oxygen (O). When the magnetization direction of the storage layer 41 is parallel to the magnetization direction of the reference layer 42, the magnetoresistance effect element 40 exhibits a low-resistance state with relatively low resistance, whereas when the magnetization direction of the storage layer 41 is antiparallel to the magnetization direction of the reference layer 42, the magnetoresistance effect element 40 exhibits a high-resistance state with relatively high resistance. Thus, the magnetoresistance effect element 40 can store binary data according to the resistance state.

The magnetoresistance effect element 40 is a spin transfer torque (STT)-type magnetoresistance effect element having perpendicular magnetization. That is, the magnetization direction of the storage layer 41 is perpendicular to its main surface, and the magnetization direction of the reference layer 42 is perpendicular to its main surface.

Note that FIG. 2 shows a bottom-free type magnetoresistance effect element in which the storage layer 41 is located on a lower side of the reference layer 42, but a top-free type magnetoresistance effect element in which the storage layer 41 is located on an upper side of the reference layer 42 can as well be used.

The lower structure 100 includes the selector 50 and the interlayer insulation layer 81.

The selector 50 is a two-terminal switching element and includes an electrode 51, a columnar electrode 52, and a selector material layer (switching material layer) 53 provided between the electrode 51 and the columnar electrode 52. The electrode 51 functions as the bottom electrode of the selector 50, and the columnar electrode 52 functions as the top electrode of the selector 50. The electrode 51 is connected to the respective one of the first wiring lines 10 shown in FIG. 1, and the columnar electrode 52 is connected to the bottom electrode 61, which will be described later.

When a voltage higher than or equal to a threshold voltage is applied between the electrode 51 and the columnar electrode 52, the selector 50 shifts from an off state to an on state, and an on current flows through the selector 50. As a result, a current flows to the magnetoresistance effect element 40 connected in series with the selector 50, and thus write or read can be carried out on the magnetoresistance effect element 40.

The interlayer insulating layer 81 is formed of silicon oxide and surrounds a side surface of the selector 50 (side surface of the electrode 51, side surface of the columnar electrode 52, and side surface of the selector material layer 53). An upper portion of the columnar electrode 52 protrudes from the upper surface of the interlayer insulating layer 81.

The bottom electrode 61 functions as a bottom electrode for the magnetoresistance effect element 40 and is provided on the lower structure 100. More specifically, the bottom electrode 61 is provided on the columnar electrode 52 and on the interlayer insulating layer 81, covers the upper portion of the columnar electrode 52, and is connected to the columnar electrode 52. As described above, since the upper portion of the columnar electrode 52 protrudes from the interlayer insulating layer 81, the lower surface of the bottom electrode 61 has a recess based on the upper portion of the columnar electrode 52. On the other hand, the upper surface of the bottom electrode 61 is planarized. Further, the magnetoresistance effect element 40 is connected to the selector 50 via the bottom electrode 61.

The bottom electrode 61 is formed of a conductive material, and the oxide of the conductive material for the bottom electrode 61 is an insulator having insulating properties. More specifically, the conductive material for the bottom electrode 61 contains elements selected from hafnium (Hf), aluminum (Al), silicon (Si), iron (Fe), cobalt (Co), tantalum (Ta), magnesium (Mg) and gadolinium (Gd).

The top electrode 62 functions as the top electrode for the magnetoresistance effect element 40 and is connected to the second wiring lines 20 shown in FIG. 1. In other words, the magnetoresistance effect element 40 and the respective one of the second wiring lines 20 are connected to each other via the top electrode 62.

The oxide insulating layer 70 is formed of an oxide of the conductive material for the bottom electrode 61. More specifically, the oxide insulating layer 70 is formed of an oxide of an etching product (conductive material) produced when the pattern of the bottom electrode 61 is formed. The oxide insulating layer 70 includes a first portion 71, a second portion 72, and a third portion 73.

The first portion 71 corresponds to a portion provided on a side surface of the bottom electrode 61 and is provided along the side surface of the bottom electrode 61. The second portion 72 corresponds to a portion provided on a side surface of the magnetoresistance effect element 40 and is provided along the side surface of the magnetoresistance effect element 40. In this embodiment, the second portion 72 corresponds to the portions provided on side surfaces of the magnetoresistance effect element 40 and the top electrode 62, and is provided along the side surface of the magnetoresistance effect element 40 and the side surface of the top electrode 62. The third portion 73 corresponds to a portion provided on the lower structure 100 and adjacent to the bottom electrode 61. More specifically, the third portion 73 is provided on the interlayer insulating layer 81 and between a respective adjacent pair of the bottom electrodes 61.

The interlayer insulating layer 82 is formed of silicon oxide so as to cover the oxide insulating layer 70.

Next, a method of manufacturing the magnetic memory device of this embodiment will be described with reference to FIGS. 3 to 6 and FIG. 2.

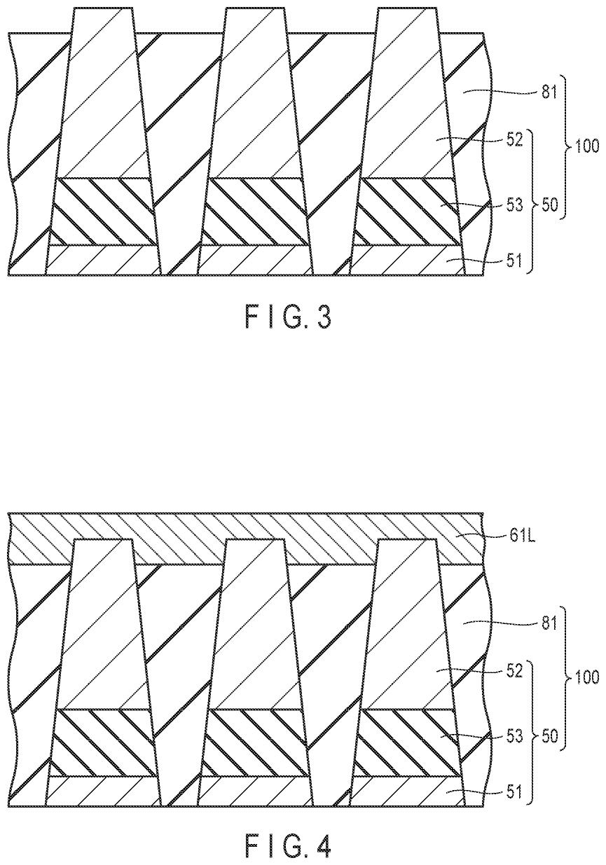

First, as shown in FIG. 3, the lower structure 100 including the selector 50 and the interlayer insulating layer 81 is formed above the semiconductor substrate (not shown). More specifically, after forming the selector 50, the interlayer insulating layer 81, which covers the selector 50 is formed, and then the interlayer insulating layer 81 is planarized. In this planarization process, it is difficult to match the height of the upper surface of the columnar electrode 52 of the selector 50 and the upper surface of the interlayer insulating layer 81 with each other. In this embodiment, the upper surface of the columnar electrode 52 is higher than the upper surface of the interlayer insulating layer 81, and the upper portion of the columnar electrode 52 protrudes from the upper surface of the interlayer insulating layer 81.

Next, as shown in FIG. 4, a bottom electrode layer 61L is formed on the lower structure 100 obtained in the step show in FIG. 3. More specifically, after depositing the bottom electrode layer 61L, chemical mechanical polishing (CMP) is performed. With the CMP process, the bottom electrode layer 61L that includes a planarized upper surface and covers the upper portion of the columnar electrode 52 is obtained. As described, the bottom electrode layer 61L covers the upper portion of the columnar electrode 52, and the upper surface of the bottom electrode layer 61L is planarized; therefore, the thickness of the bottom electrode layer 61L after the CMP process is greater. With the CMP process, the exposure of the upper surface of the columnar electrode 52 should be avoided. If the upper surface of the columnar electrode 52 is exposed, a flat surface may not be obtained due to the difference in CMP speed. In order to avoid this, the CMP process is performed to make the level of the upper surface of the bottom electrode layer 61L after the CMP process to be higher than the level of the upper surface of the columnar electrode 52.

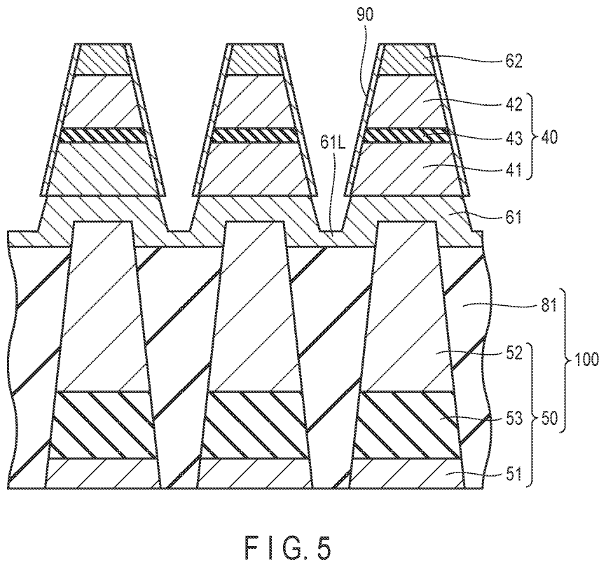

Next, as shown in FIG. 5, a magnetoresistance effect element layer is formed on the structure obtained in the step of FIG. 4. Further, a hard mask is formed on the magnetoresistance effect element layer, and the magnetoresistance effect element layer and the bottom electrode layer 61L are patterned using the hard mask as a mask. More specifically, patterning is performed using ion beam etching (IBE). Thus, the pattern of the magnetoresistance effect element 40 and the pattern of the bottom electrode 61 are obtained. Further, the thickness of the hard mask is reduced, and the hard mask whose thickness is reduced remains on the magnetoresistance effect element 40 as the top electrode 62.

By the patterning process described above, each adjacent pair of the magnetoresistance effect elements 40 is completely separated. On the other hand, since the thickness of the bottom electrode layer 61L is great, the hard mask may be lost if such an attempt is made as to completely remove the bottom electrode layer 61L between each adjacent pair of the bottom electrodes 61 by patterning. Therefore, a portion of the bottom electrode layer 61L remains between each adjacent pair of the bottom electrodes 61. Note that if it is possible to completely remove the bottom electrode layer 61L between each adjacent pair of the bottom electrodes 61 by patterning, the bottom electrode layer 61L does not have to remain between each adjacent pair of the bottom electrodes 61.

Further, after the patterning, etching products generated by etching with IBE adhere to the side surface of the magnetoresistance effect element 40 and that of the top electrode 62, forming an etching product layer 90. In the etching process, the bottom electrode layer 61L is etched last. Therefore, the etching product layer 90 is substantially formed by the conductive material of the bottom electrode layer 61L.

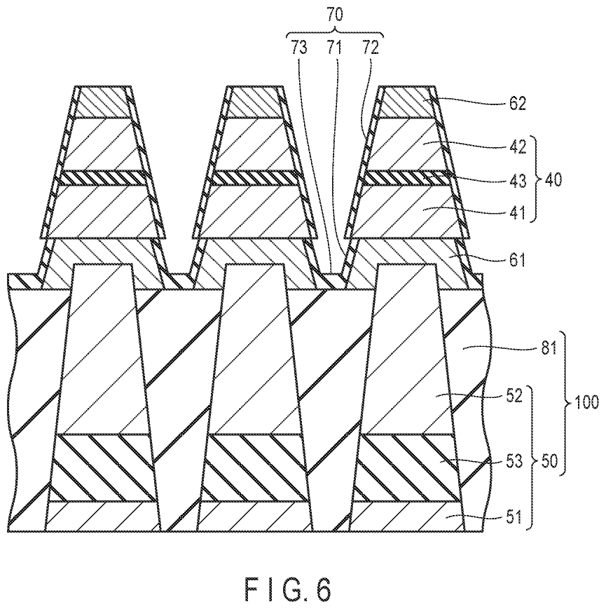

Next, as shown in FIG. 6, oxidation process is performed on the structure obtained in the step of FIG. 5. With this oxidation process, the oxide insulating layer 70 is formed. More specifically, an oxide insulating layer 70 is formed, which includes a first portion 71 formed on the side surface of the bottom electrode 61, a second portion 72 formed on the side surfaces of the magnetoresistance effect element 40 and the top electrode 62, and a third portion 73 formed on the interlayer insulating layer 81 of the lower structure 100.

The first portion 71 is formed by oxidation of the side surface portion of the bottom electrode 61. Thus, the first portion 71 is formed of an oxide of the conductive material for the bottom electrode 61. The second portion 72 is formed by oxidation of the etching product layer 90. As already described, the etching product layer 90 is substantially formed of the conductive material for the bottom electrode layer 61L. Therefore, the second portion 72 as well is formed of an oxide of the conductive material for the bottom electrode 61. The third portion 73 is formed by oxidation of the bottom electrode layer 61L remaining between each adjacent pair of the bottom electrodes 61 after the patterning process in FIG. 5. Therefore, the third portion 73 as well is formed of an oxide of the conductive material for the bottom electrode 61. As already described, the oxide of the conductive material for the bottom electrode 61 is an insulator. Therefore, the first portion 71, the second portion 72, and the third portion 73 of the oxide insulating layer 70 are all formed of insulators.

Note that in the case where no bottom electrode layer 61L remains between adjacent bottom electrodes 61 after the patterning process in FIG. 5, the third portion 73 of the oxide insulating layer 70 is not formed in the oxidation process described above.

After the step of FIG. 6, an interlayer insulating layer 82 which covers the oxide insulating layer 70 is formed, and thus such a structure as shown in FIG. 2 is obtained.

As described above, in this embodiment, the first portion 71, the second portion 72, and the third portion 73 of the oxide insulating layer 70 are formed by the oxidation process shown in FIG. 6. The oxide insulating layer 70 is formed of the oxides of the conductive material for the bottom electrode 61, and the oxides of the conductive material for the bottom electrode 61 are insulators. With this configuration, in this embodiment, it is possible to obtain a magnetic memory device having excellent insulation properties, as described below.

That is, in this embodiment, even if the conductive material for the bottom electrode 61 adheres to the side surface of the magnetoresistance effect element 40 and the side surface of the top electrode 62 in the patterning process (etching process) of FIG. 5 to form an etching product layer 90, the etching product layer 90 is oxidized in the step of FIG. 6 to form the second portion 72 of the oxide insulating layer 70. In this manner, it is possible to prevent electrical short-circuiting defects in the magnetoresistance effect element 40.

Further, the bottom electrode layer 61L remaining between adjacent bottom electrodes 61 after the patterning process of FIG. 5 is also oxidized in the step of FIG. 6 to form the third portion 73 of the oxide insulating layer 70. Thus, electrical short-circuiting defects between adjacent bottom electrodes 61 can be prevented. Furthermore, since a portion of the bottom electrode layer 61L may remain between adjacent bottom electrodes 61 after the patterning process in FIG. 5, the thickness of the hard mask can be reduced.

Furthermore, in the process of FIG. 4, a thick bottom electrode layer 61L which covers the upper portion of the columnar electrode 52 is formed and the upper surface of the bottom electrode layer 61L is planarized, and therefore the upper surface level of the bottom electrode layer 61L after the CMP processing is higher than the upper surface level of the columnar electrode 52. With this configuration, even if the upper surface of the lower structure 100 formed in the process of FIG. 3 is not flat, the magnetoresistance effect element 40 can be formed on the planarized bottom electrode layer 61L. If the magnetoresistance effect element 40 is formed on a non-flat surface, the shape of the non-flat surface would be reflected in the layers constituting the magnetoresistance effect element 40 (that is, the storage layer 41, the reference layer 42, and the tunnel barrier layer 43), and the flatness of the layers constituting magnetoresistance effect element 40 will be lost. As a result, the characteristics of the magnetoresistance effect element 40 may be adversely affected.

In this embodiment, the planarized thick bottom electrode layer 61L is formed, and therefore each layer constituting the magnetoresistance effect element 40 can be formed flat, and the above-described drawbacks can be prevented.

As described above, according to this embodiment, it is possible to obtain a magnetic memory device with excellent characteristics.

### Second Embodiment

Next, the second embodiment will be described. Note that the basic items are similar to those of the first embodiment described above, and the explanation of the items described in the first embodiment will be omitted.

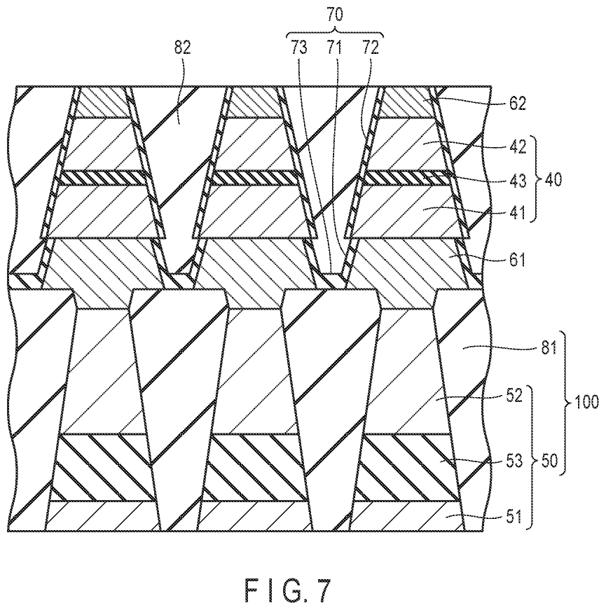

FIG. 7 is a cross-sectional view schematically showing a configuration of an area where memory cells 30 are provided in a magnetic memory device according to the second embodiment.

As can be seen from FIG. 2 as well as FIG. 7, the basic configuration of this embodiment is similar to that of the first embodiment except for the followings. That is, in the first embodiment, the upper portion of the columnar electrode 52 protrudes from the interlayer insulating layer 81 and the lower surface of the bottom electrode 61 has a recess based on the upper portion of the columnar electrode 52, whereas in this embodiment, the upper surface of the columnar electrode 52 is recessed to the upper surface of the interlayer insulating layer 81 and the lower surface of the bottom electrode 61 protrudes toward the upper surface of the columnar electrode 52. In other words, the bottom electrode 61 includes a portion protruding toward the upper surface of the columnar electrode 52.

Next, a method of manufacturing the magnetic memory device according to this embodiment will be described with reference to FIGS. 8 to 11 and FIG. 7.

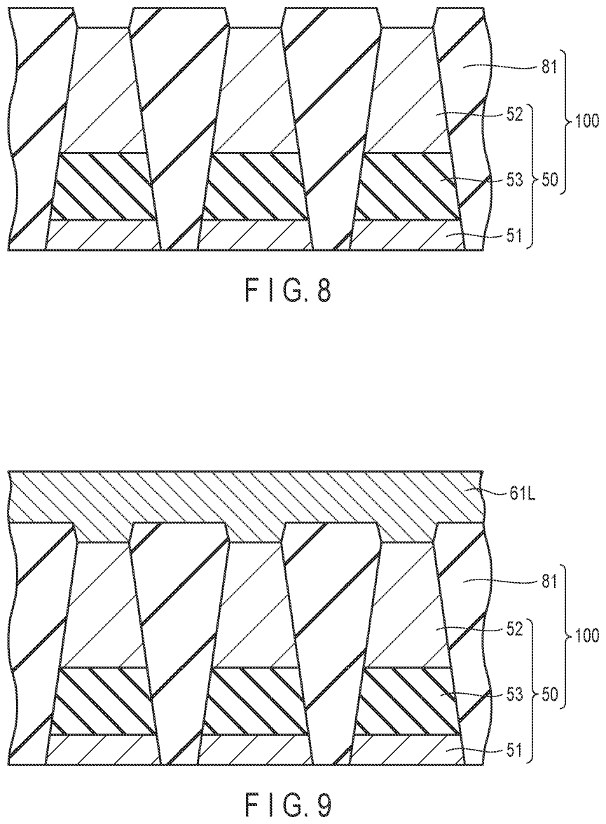

First, as shown in FIG. 8, the lower structure 100 is formed above the semiconductor substrate (not shown) in a manner similar to that of the step in FIG. 3 of the first embodiment. But, in this embodiment, when planarizing the interlayer insulating layer 81, the upper surface of the columnar electrode 52 is leveled lower than the upper surface of the interlayer insulating layer 81, and the upper surface of the columnar electrode 52 is recessed to the upper surface of the interlayer insulating layer 81.

Next, as shown in FIG. 9, the bottom electrode layer 61L is formed on the lower structure 100 in a manner similar to that of the step shown in FIG. 4 of the first embodiment. In this embodiment as well, the upper surface of the bottom electrode layer 61L is planarized and the thickness of the bottom electrode layer 61L is greater. More specifically, the level of the upper surface of the bottom electrode layer 61L before the planarization process by CMP is higher than the level of the upper surface of the interlayer insulating layer 81, and the level of the upper surface of the bottom electrode layer 61L is higher than the level of the upper surface of the interlayer insulating layer 81 even after the planarization process. Thus, both before and after the planarization process, the upper surface of the columnar electrode 52 and the upper surface of the interlayer insulating layer 81 are covered by the bottom electrode layer 61L.

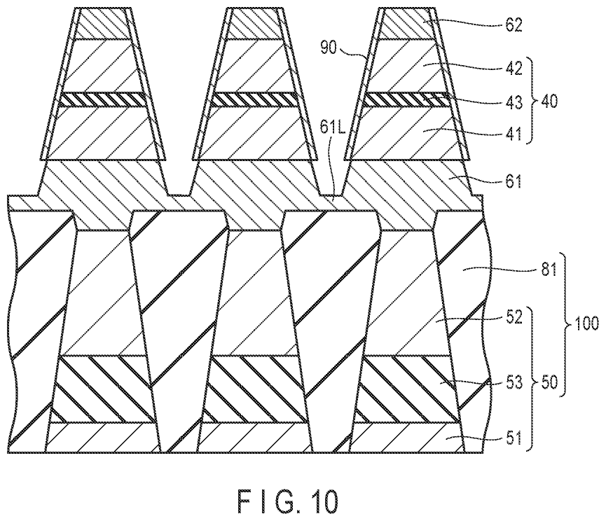

Next, as shown in FIG. 10, the magnetoresistance effect element 40, the bottom electrode 61, and the top electrode 62 are formed in a manner similar to that of the step of FIG. 5 of the first embodiment. In this embodiment as well, the etching product layer 90 is formed on the side surface of the magnetoresistance effect element 40 and the side surface of the top electrode 62, and a portion of the bottom electrode layer 61L remains between adjacent bottom electrodes 61 as in the case of the first embodiment.

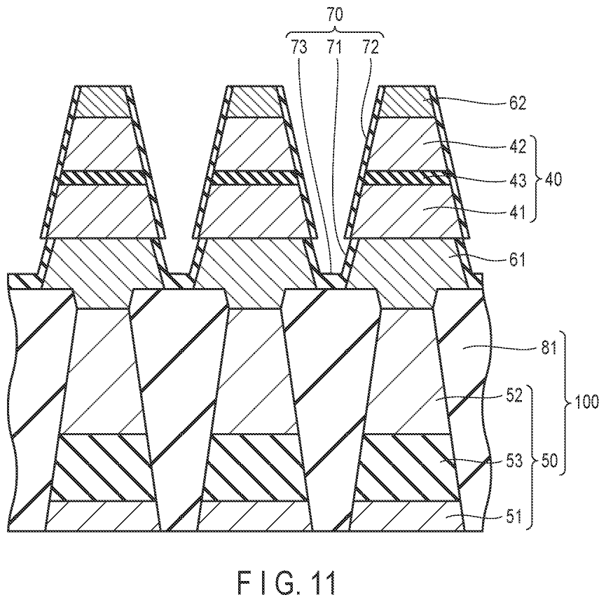

Next, as shown in FIG. 11, oxidation process is performed in a manner similar to that of the step shown in FIG. 6 of the first embodiment. With this oxidation process, an oxide insulating layer 70 including a first portion 71, a second portion 72, and a third portion 73 is formed as in the case of the first embodiment. In other words, the oxide insulating layer 70 formed of an oxide of the conductive material for the bottom electrode 61 is formed.

After the step of FIG. 11, an interlayer insulating layer 82 covering the oxide insulating layer 70 is formed, and thus such a structure as shown in FIG. 7 is obtained.

As described above, the basic configuration and the basic manufacturing method of this embodiment are similar to those of the first embodiment, and advantageous effects similar to those of the first embodiment can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a lower structure;
a bottom electrode provided on the lower structure and formed of a conductive material;
a top electrode provided above the bottom electrode;
a magnetoresistance effect element provided between the bottom electrode and the top electrode; and
an oxide insulating layer including a first portion provided on a side surface of the bottom electrode and a second portion provided on a side surface of the magnetoresistance effect element, and formed of an oxide of the conductive material.

2. The magnetic memory device of claim 1, wherein
the oxide insulating layer further includes a third portion provided on the lower structure and adjacent to the bottom electrode.

3. The magnetic memory device of claim 2, wherein
the lower structure includes an interlayer insulating layer, and
the third portion is provided on the interlayer insulating layer.

4. The magnetic memory device of claim 1, wherein
the lower structure includes a columnar electrode, and
the bottom electrode is connected to the columnar electrode.

5. The magnetic memory device of claim 4, wherein
the bottom electrode has a recess based on an upper portion of the columnar electrode.

6. The magnetic memory device of claim 4, wherein
the bottom electrode has a portion protruding toward an upper surface of the columnar electrode.

7. The magnetic memory device of claim 4, wherein
the lower structure further includes an interlayer insulating layer surrounding a side surface of the columnar electrode.

8. The magnetic memory device of claim 1, wherein
an upper surface of the bottom electrode is planarized.

9. The magnetic memory device of claim 1, wherein
the conductive material contains an element selected from hafnium (Hf), aluminum (Al), silicon (Si), iron (Fe), cobalt (Co), tantalum (Ta), magnesium (Mg) and gadolinium (Gd).

10. The magnetic memory device of claim 1, wherein
the magnetoresistance effect element includes a first magnetic layer having a variable magnetization direction, a second magnetic layer having a fixed magnetization direction, and a nonmagnetic layer provided between the first magnetic layer and the second magnetic layer.

11. The magnetic memory device of claim 1, wherein
the lower structure includes a switching element connected to the magnetoresistance effect element via the bottom electrode.

12. The magnetic memory device of claim 11, further comprising:
a first wiring line extending along a first direction and connected to the switching element; and
a second wiring line extending along a second direction intersecting the first direction and connected to the magnetoresistance effect element via the top electrode.
